(19) United States
(12) Patent Application Publication
(10) Pub. No.: US 2007/0164752 A1
(43) Pub. Date: Jul. 19, 2007

(54) Biometric information transmitter

(76) Inventor: Kazuo Kato, Chiba-shi (JP)

Correspondence Address: BRUCE L. ADAMS, ESQ., SUITE 1231, 17 BATTERY PLACE, NEW YORK, NY, 10004, US

(21) Appl. No.: 11/646,920

(22) Filed: Dec. 28, 2006

(30) Foreign Application Priority Data
Jan. 18, 2006 (JP) 2006-009907

(51) Int. Cl. G01R 27/02

(52) U.S. Cl. 324/606

(57) ABSTRACT

To reduce power consumption in transmitting biometric information signal by wireless. A heart beat detecting circuit amplifies a heart beat signal from an electrode and outputs a biometric detecting signal A having a predetermined time width in synchronism with heart beat of the heart. A voltage comparator, a pulse counting circuit and a control signal generating circuit control an antenna driving circuit such that an antenna circuit is driven when a signal level of a drive signal for driving the antenna circuit by the antenna driving circuit is lowered during a time period of outputting the biometric detecting signal A. The antenna driving circuit excites a resonance circuit comprising a coil L and a capacitor C for an antenna of the antenna circuit in response to the control. A biometric information signal of a burst signal type in correspondence with the heart beat signal is outputted by wireless from the antenna coil L, thereby, power consumption in transmitting by wireless is reduced.

### BACKGROUND OF THE INVENTION

1. Field of the Invention

The present invention relates to a biometric information transmitter for detecting to transmit a biometric signal of heart beat or the like.

2. Description of the Prior Art

In a background art, there has been developed a biometric information measuring apparatus for measuring biometric information of a person of heart beat, pulse, number of walk or the like.

For example, as a heart beat meter constituting a kind of a biometric information measuring apparatus, there has been developed a heart beat meter mounting a biometric information transmitter for detecting a heart beat signal constituting a biometric signal and transmitting a corresponding biometric information signal by wireless to the chest of a measured person in a state of being brought into press contact therewith by a chest belt, receiving the biometric information by a biometric information receiver in a shape of a wristwatch and displaying the heartbeat value or the like.

According to the transmitter for the heart beat meter of the background art, a burst signal in synchronism with the heart beat signal is generated and the heart beat signal is transmitted by a type of the burst signal (refer to, for example, JT-A-8-505308).

Generally, the biometric information transmitter is driven by a battery and utilizes free oscillation by a resonance circuit when the burst signal is generated for power saving formation.

FIG. 5 is a block diagram of the biometric information transmitter of the background art for transmitting heart beat information by the burst signal. In FIG. 5, the biometric information transmitter includes an electrode 501 for outputting a heart beat signal in heart beat of the heart, a heart beat detecting circuit 502 for amplifying the heart beat signal from the electrode 501 and outputting a heart beat detecting signal having a predetermined time width in synchronism with heart beat of the heart, a CR oscillation circuit 503 including a capacitor (C), resistor (R) for oscillating by a predetermined frequency, an antenna driving circuit 504, and an antenna circuit 505 including a resonance circuit constituted by a coil and a capacitor for the antenna.

As shown by a timing chart of FIG. 6, the electrode 501 outputs the heart beat signal generated in heart beat of the heart, the heart beat detecting circuit 502 outputs the heart beat detecting signal A constituting a low level signal of a predetermined time width (for example, about 10 msec) in synchronism with heart beat of the heart by amplifying the heart beat signal from the electrode 501. The CR oscillation circuit 503 carries out oscillation operation during a time period of outputting the heart beat detecting signal A. The CR oscillation circuit 503 outputs a control signal B constituting a pulse signal having an oscillation frequency of a predetermined frequency (for example, 1.25 kHz) and constituting a high level time period by a predetermined width (for example, 100 μsec).

The antenna driving circuit 504 intermittently drives the antenna circuit 505 in response to the control signal B outputted by the CR oscillation circuit 503. According to the antenna circuit 505, an LC resonance circuit constituted by an antenna coil and a capacitor is excited by being driven by a drive signal F from the antenna driving circuit 504, and after driving the LC resonance circuit, a signal level is gradually attenuated while carrying out free oscillation.

As shown by FIG. 6, by repeating to drive the antenna circuit 505 before reducing an amplitude of the drive signal F by an intermittent drive control by the control signal B outputted by the CR oscillation circuit 503, the biometric information signal of a type of a burst signal having a predetermined frequency (for example, 5 kHz) in correspondence with the heart beat signal can be outputted by wireless by low power consumption.

FIG. 7 is a detailed circuit diagram of the antenna driving circuit 504 and the antenna circuit 505 and portions the same as those of FIG. 5 are attached with the same notations.

In FIG. 7, a resistor Rb and a transistor Tr constitute the antenna driving circuit 504, a resonance circuit comprising an antenna coil L and a capacitor C, a resistor Rp and a capacitor Cp constitute the antenna circuit 505. Further, the resistor Rp is a protection resistor for restricting a current and the capacitor Cp is a smoothing capacitor.

When the control signal B is inputted from the CR oscillation circuit 503 to the antenna driving circuit 504, the transistor Tr is made ON, a current flows to the coil L, and the biometric information signal of the type of the burst signal in correspondence with the heart beat signal is transmitted from the coil L to a biometric information receiver (not illustrated) by wireless.

However, a resonance frequency of the CR oscillation circuit 503 and a resonance frequency of the LC resonance circuit constituting the antenna circuit 505 are dispersed by tolerances of parts constituting the respective circuits without being correlated with each other. During a time period in which a voltage of driving the antenna circuit 505 rises, at the antenna circuit 505, a current is increased from power source Vcc in a direction of ground potential and current flowing from the power source Vcc is increased.

Therefore, when the CR oscillation circuit 503 supplies control signal B to the antenna driving circuit 504 at a timing at which the signal F of driving the antenna circuit 505 rises, as shown by FIG. 8, not only a current I9 flows to the coil L by way of the capacitor C and the capacitor Cp but also a current I8 flowing from the power source Vcc in the direction of the ground potential by way of the coil L is increased and therefore, there poses a problem that power consumption in transmitting the biometric information signal by wireless is increased.

The invention has been carried out in view of the above-described problem and it is a problem thereof to reduce power consumption in transmitting the biometric information signal by wireless.

### SUMMARY OF THE INVENTION

According to the invention, there is provided a biometric information transmitter characterized in a biometric information transmitter including biometric signal detecting means for detecting a biometric signal and outputting a corresponding biometric detecting signal, driving means for driving an antenna circuit by a drive signal, the antenna circuit for outputting a biometric information signal in correspondence with the biometric detecting signal by wireless by being driven by the driving means, and controlling means for controlling the driving means to drive the antenna circuit, wherein the controlling means controls the driving means to drive the antenna circuit when a signal level of the drive signal is lowered.

The controlling means controls the driving means to drive the antenna circuit when the signal level of the drive signal is lowered.

Here, there may be constructed a constitution in which the controlling means comprises a voltage comparator for comparing the drive signal with a predetermined reference level and outputting a signal in accordance with the signal level of the drive signal, dividing means for dividing an output signal of the voltage comparator by a predetermined dividing ratio, and a control signal generating circuit for outputting a control signal for controlling the driving means to output the drive signal in response to an output signal of the dividing means, wherein the control signal generating circuit outputs the control signal to the driving means when the signal level of the drive signal is lowered.

Further, there may be constructed a constitution in which the biometric signal detecting means detects the biometric signal and outputs the biometric detecting signal having a predetermined time width, wherein the control signal generating circuit outputs the control signal to the driving means during a time period of outputting the biometric detecting signal.

Further, there may be constructed a constitution in which the control signal generating circuit outputs the control signal to the driving means when the signal level of the drive signal is lowered by outputting the control signal in response to an edge in a predetermined direction of the biometric detecting signal and outputting the control signal in response to an edge in a predetermined direction of each output signal of the dividing means during the time period of outputting the biometric detecting signal.

Further, there may be constructed a constitution in which the voltage comparator comprises a first voltage dividing circuit for dividing a voltage of the drive signal by a predetermined voltage dividing ratio to be outputted, a second voltage dividing circuit for dividing a power source voltage by a voltage dividing ratio the same as the predetermined voltage dividing ratio of the first voltage dividing circuit to be outputted, and a comparing circuit for comparing output signals of the first voltage dividing circuit and the second voltage dividing circuit and outputting a signal in accordance with a result of the comparison.

Further, the biometric information transmitter may be constituted to include a battery and to be operated by constituting a power source by the battery.

### BRIEF DESCRIPTION OF THE SEVERAL VIEWS OF THE DRAWINGS

A preferred form of the present invention is illustrated in the accompanying drawings in which:

FIG. 1 is a block diagram of the biometric information transmitter according to an embodiment of the invention;

FIG. 2 is a partial circuit diagram of the biometric information transmitter according to the embodiment of the invention;

FIG. 3 is a timing chart of the biometric information transmitter according to the embodiment of the invention;

FIG. 4 is a diagram for explaining operation of the biometric information transmitter according to the embodiment of the invention;

FIG. 5 is a block diagram of a biometric information transmitter of a background art;

FIG. 6 is a timing chart of the biometric information transmitter of the background art;

FIG. 7 is a partial circuit diagram of the biometric information transmitter of the background art; and

FIG. 8 is a diagram for explaining operation of the biometric information transmitter of the background art.

### DETAILED DESCRIPTION OF THE PREFERRED EMBODIMENTS

An explanation will be given of a biometric information transmitter according to an embodiment of the invention as follows. Further, the embodiment of the invention will be explained by taking an example of a transmitter for a heart beat meter for transmitting a biometric information signal of a burst signal type in correspondence with a heart beat signal by wireless as a biometric information transmitter.

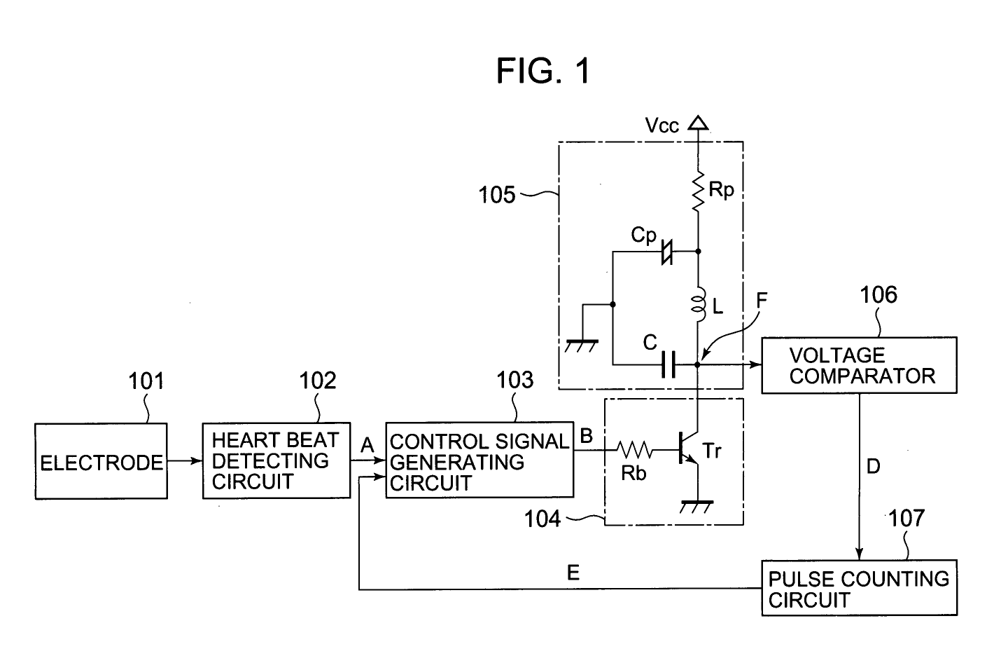

FIG. 1 is a block diagram of a transmitter for a heart beat meter according to the embodiment of the invention. In FIG. 1, the transmitter for the heart beat meter includes an electrode 101 for outputting a heart beat signal of a measured person constituting a biometric signal, a heart beat detecting circuit 102 for outputting a biometric detecting signal having a width of a predetermined time period in synchronism with heart beat of the heart by amplifying the signal from the electrode 101, a control signal generating circuit 103 for generating a control signal in response to the biometric detecting signal from the heart beat detecting circuit 102, an antenna driving circuit 104 for driving an antenna circuit 105 by a drive signal, the antenna circuit 105, a voltage comparator 106 and a pulse counting circuit 107.

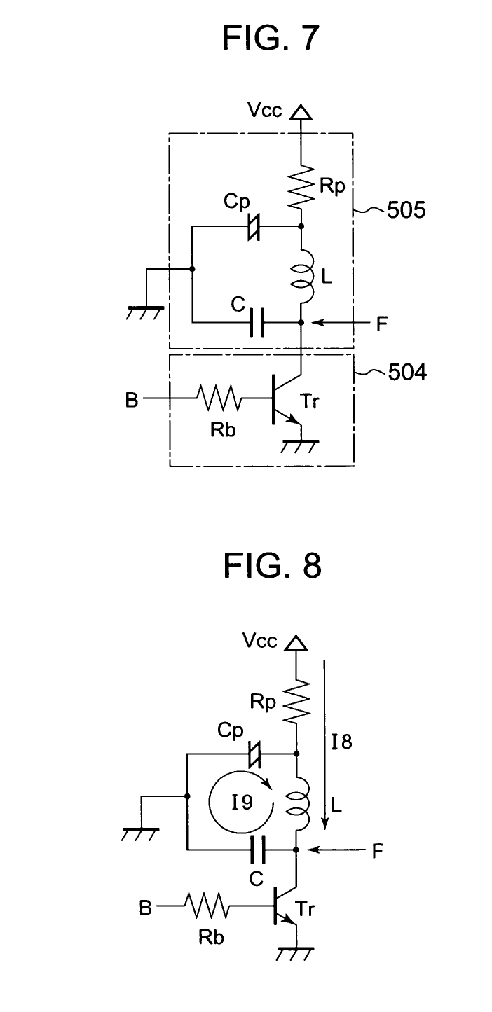

Circuit constitutions per se of the antenna driving circuit 104 and the antenna circuit 105 are respectively the same as the constitutions of the antenna driving circuit 504 and the antenna circuit 505 shown in FIG. 7. That is, the antenna driving circuit 104 includes the transistor Tr and the input resistor Rb connected to the base of the transistor Tr. Further, the antenna circuit 105 includes the resonance circuit constituted by the coil L for the antenna and the capacitor C, the protecting resistor Rp for restricting the current and the smoothing capacitor Cp.

Further, the electrode 101 and the heart beat detecting circuit 102 constitute biometric signal detecting means for detecting the biometric signal and outputting the corresponding biometric detecting signal, the antenna driving circuit 104 constitutes driving means for driving the antenna circuit 105 by the drive signal, the control signal generating circuit 103, the voltage comparing circuit 106 and the pulse counting circuit 107 constitute controlling means for controlling the antenna driving circuit 104 to control the antenna circuit 105. The controlling means controls the antenna driving circuit 104 to drive the antenna circuit 105 when the signal level of the drive signal is lowered. Further, the antenna circuit 105 is operated such that the resonance circuit is excited by being driven by the antenna driving circuit 104, the biometric information signal in correspondence with the biometric signal is outputted by wireless thereafter, the signal level is gradually attenuated.

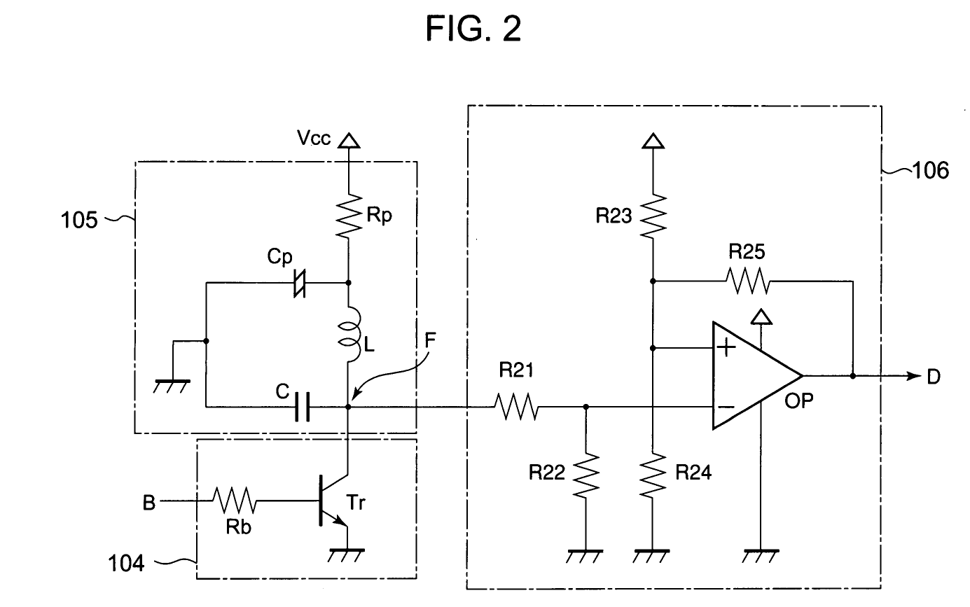

FIG. 2 is a detailed circuit diagram of the antenna driving circuit 104, the antenna circuit 105 and the voltage comparator 106, and portions the same as those of FIG. 1 are attached with the same notations.

The voltage comparator 106 includes resistors R21, R22, R23, R24, R25 and an operation amplifier OP. A negative input portion of the amplifier OP is inputted with a signal a voltage of which is divided by a predetermined voltage dividing ratio by the R21 and the resistor R22, further, a positive input potion of the amplifier OP is inputted with a signal a voltage of which is divided by a voltage dividing ratio the same as the predetermined voltage dividing ratio by the resistor R23 and the resistor R24. The resistor R21 and the resistor R22 constitute a first voltage dividing circuit for dividing a voltage of an output signal of the antenna circuit 105 by a predetermined voltage dividing ratio, further, the resistor R23 and the resistor R24 constitute a second voltage dividing circuit for diving a voltage of a power source voltage Vcc by a voltage dividing ratio the same as that of the first voltage dividing circuit.

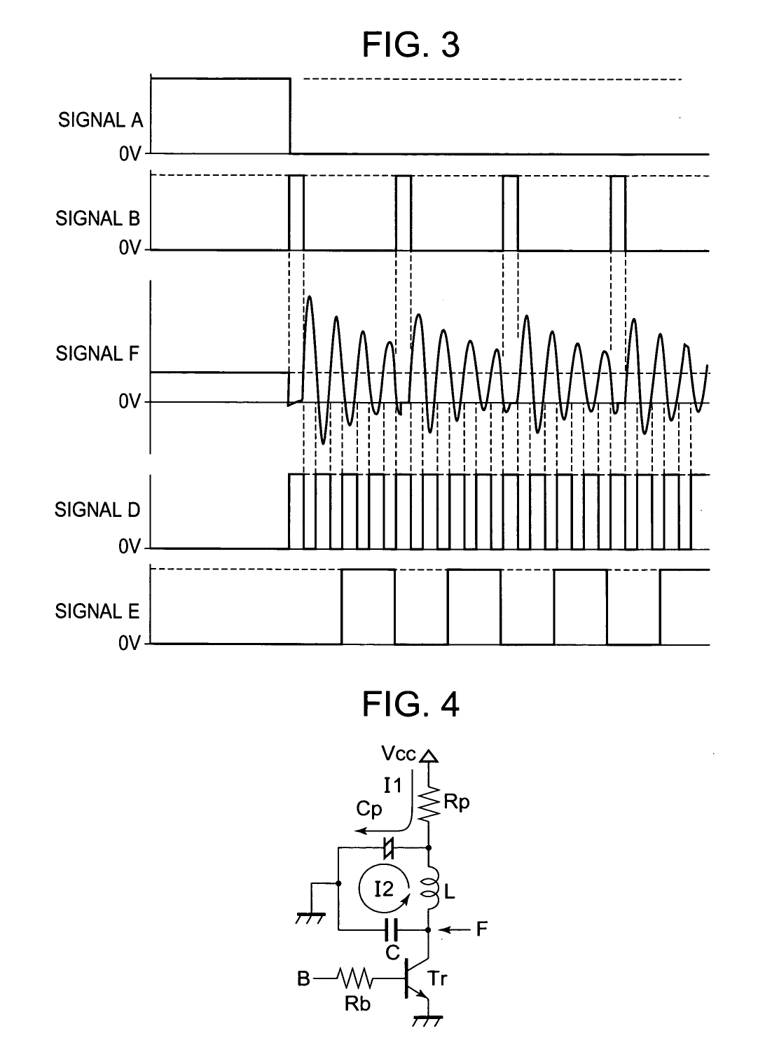

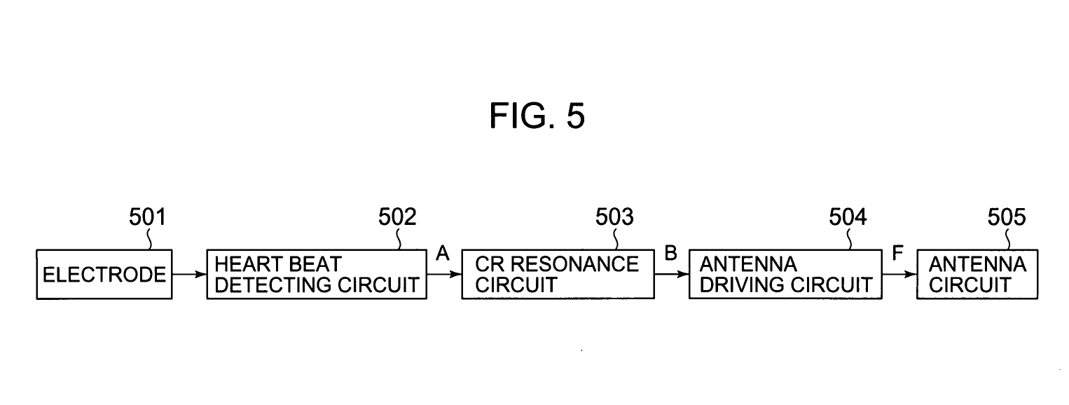

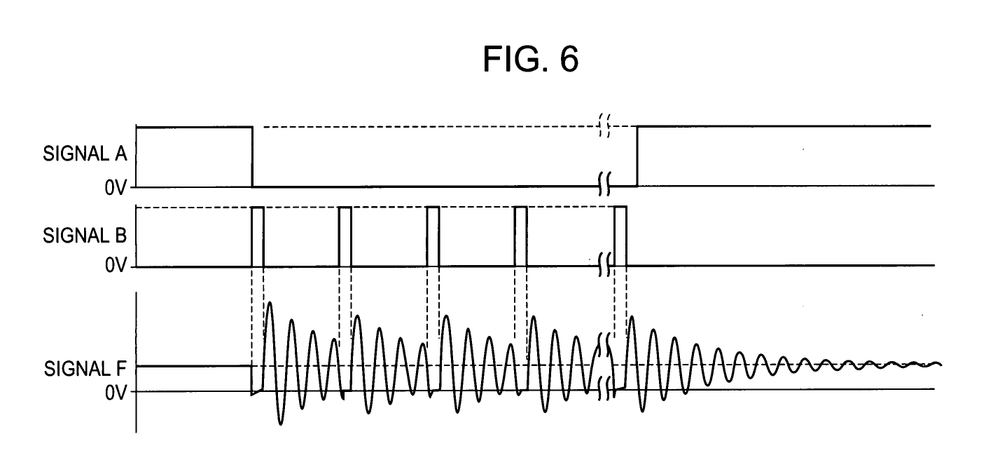

FIG. 3 is a timing chart for explaining operation of the embodiment of the invention. Further, FIG. 4 is a diagram for explaining operation of the embodiment of the invention.

The operation of the embodiment of the invention will be explained in details in reference to FIG. 1 through FIG. 4 as follows.

As shown by FIG. 3, the electrode 101 outputs the heart beat signal of the human body, the heart beat detecting circuit 102 amplifies the signal from the electrode 101 and outputs the biometric detecting signal A constituting a low level signal having a predetermined time width (for example, about 10 msec) in synchronism with the heart beat of the hearts. The control signal generating circuit 103 outputs the control signal B constituting a pulse signal having a predetermined time width in response to an edge in a predetermined direction (according to the embodiment, fall edge) of the biometric detecting signal A.

According to the antenna driving circuit 104, the transistor Tr drives the antenna circuit 105 to an ON state in response to an edge in a predetermined direction (according to the embodiment, rise edge) of the control signal B inputted by way of the resistor Rb, and the transistor Tr is maintained in an ON state during a time period in which the control signal B is at high level.

Thereby, the antenna circuit 105 is driven by the antenna drive circuit 104 by a signal of a voltage indicated by the drive signal F. In the antenna circuit 105, a current flows in the coil L by being driven by the drive signal F to generate the biometric information signal of a burst signal type in correspondence with the heart beat signal. In this way, the biometric information signal of the burst signal style is generated by utilizing a free oscillation by exciting the resonance circuit constituted by the coil L and the capacitor C for the antenna. The biometric information signal generated by the antenna circuit 105 is outputted to the biometric information receiver (not illustrated) by wireless.

On the other hand, the voltage comparator 106 compares the drive signal F with a reference signal at a predetermined voltage level, and outputs a comparison result signal D in accordance with a result of the comparison (a high level signal when the drive signal F is at a voltage level equal to or lower than the predetermined reference signal, and a low level signal when the drive signal F is at a voltage level exceeding the predetermined reference signal). That is, the amplifier OP compares a signal constituted by dividing a voltage of the drive signal F by the first voltage dividing circuit, and a signal constituted by dividing the power source voltage Vcc by the second voltage dividing circuit and outputs the comparison result signal D at a high level when a signal of the first voltage dividing circuit is at a voltage level equal to or lower than a signal of the second voltage dividing circuit and at a low level when the signal of the first voltage dividing circuit is at a voltage level exceeding the signal of the second voltage dividing circuit. Thereby, the edge in the predetermined direction (the rise edge according to the embodiment) of the comparison result signal D corresponds to a state in which the voltage level of the drive signal F is lowered.

The pulse counting circuit 107 outputs a signal E a signal level of which is reversed at every time of counting 2 pieces of the edge in the predetermined direction (the rise edge according to the embodiment) of the comparison result signal D. That is, the pulse counting circuit 107 functions as dividing means and outputs the signal E constituted by dividing the comparison result signal D by ½.

The control signal generating circuit 103 outputs the control signal B in response to each edge in the predetermined direction (the fall edge according to the embodiment) of the signal E outputted from the pulse counting circuit 107 in case of low level state for the biometric detecting signal A from heart beat detecting circuit 102.

The antenna driving circuit 104 drives the antenna circuit 105 in response to each control signal B as described above. Thereby, the biometric information signal of the burst signal type in correspondence with the heart beat signal is outputted by wireless from the coil L.

At this occasion, as shown by FIG. 3, the control signal generating circuit 103 supplies the control signal B to the antenna drive circuit 104 when the voltage level of the drive signal F is lowered. Therefore, the antenna drive circuit 104 restarts to drive the antenna circuit 105 when the voltage level of the drive signal F is lowered in response to the control signal B.

In this case, as shown by FIG. 4, while a current I1 flows to the capacitor Cp from the power source Vcc by way of the resistor Rp, a current I2 flows to the coil L by way of the capacitor C and the capacitor Cp. The current I1 flowing from the power source Vcc to the capacitor Cp is small, further, most of the current I2 flowing to the coil L is derived from charge charged to the capacitor Cp.

Therefore, the current flowing to the coil L can be reduced and therefore, power consumption of the power source Vcc can be reduced.

Further, although the current flowing to the coil L is reduced, a level of the biometric information signal outputted from the coil L becomes large. This is interpreted such that a battery is used as the power source, and an internal impedance thereof effects an influence thereon.

Although the embodiment has been explained by taking an example of the transmitter for the heart beat meter, the invention is not limited thereto but is applicable to various biometric information transmitters for detecting a biometric signal generated periodically to be outputted by wireless. For example, the invention is preferable also to a biometric information transmitter for detecting pulse or walking to be transmitted by wireless other than heart beat.

According to the invention power consumption by wireless transmission can be reduced.

The invention can be utilized for a biometric information transmitter for detecting a biometric signal of heart beat, pulse, walking or the like of a person to be transmitted not only as a heart beat meter but also as a pulsimeter, passo meter or the like.

What is claimed is:

1. A biometric information transmitter comprising:
biometric signal detecting means for detecting a biometric signal and outputting a corresponding biometric detecting signal;
driving means for driving an antenna circuit by a drive signal;
the antenna circuit for outputting a biometric information signal in correspondence with the biometric detecting signal by wireless by being driven by the driving means; and
controlling means for controlling the driving means to drive the antenna circuit;
wherein the controlling means controls the driving means to drive the antenna circuit when a signal level of the drive signal is lowered.

2. A biometric information transmitter according to claim 1, wherein the controlling means comprises a voltage comparator for comparing the drive signal with a predetermined reference level and outputting a signal in accordance with the signal level of the drive signal, dividing means for dividing an output signal of the voltage comparator by a predetermined dividing ratio, and a control signal generating circuit for outputting a control signal for controlling the driving means to output the drive signal in response to an output signal of the dividing means;
wherein the control signal generating circuit outputs the control signal to the driving means when the signal level of the drive signal is lowered.

3. A biometric information transmitter according to claim 2, wherein the biometric signal detecting means detects the biometric signal and outputs the biometric detecting signal having a predetermined time width;
wherein the control signal generating circuit outputs the control signal to the driving means during a time period of outputting the biometric detecting signal.

4. A biometric information transmitter according to claim 3, wherein the control signal generating circuit outputs the control signal to the driving means when the signal level of the drive signal is lowered by outputting the control signal in response to an edge in a predetermined direction of the biometric detecting signal and outputting the control signal in response to an edge in a predetermined direction of each output signal of the dividing means during the time period of outputting the biometric detecting signal.

5. A biometric information transmitter according to claim 2, wherein the voltage comparator comprises a first voltage dividing circuit for dividing a voltage of the drive signal by a predetermined voltage dividing ratio to be outputted, a second voltage dividing circuit for dividing a power source voltage by a voltage dividing ratio the same as the predetermined voltage dividing ratio of the first voltage dividing circuit to be outputted, and a comparing circuit for comparing output signals of the first voltage dividing circuit and the second voltage dividing circuit and outputting a signal in accordance with a result of the comparison.

6. A biometric information transmitter according to claim 1 further comprising:
a battery and being operated by constituting a power source by the battery.
